(19) United States
(12) Patent Application Publication
(10) Pub. No.: US 2026/0176747 A1
(43) Pub. Date: Jun. 25, 2026

(54) DEPOSITION OF HALIDE-FREE METAL FILMS USING NOBLE METAL CATALYSTS

(71) Applicant: Applied Materials, Inc., Santa Clara, CA (US)

(72) Inventors: Andrea Leoncini, Singapore (SG); Yong Jin Kim, Albany, CA (US); Jiecong Tang, Singapore (SG); Mark Saly, Santa Clara, CA (US)

(73) Assignee: Applied Materials, Inc., Santa Clara, CA (US)

(21) Appl. No.: 18/989,397

(22) Filed: Dec. 20, 2024

(51) Int. Cl. C23C 16/18; C23C 16/455

(52) U.S. Cl. CPC C23C 16/18; C23C 16/45527

(57) ABSTRACT

Methods for depositing metal films on a semiconductor substrate are described. A noble metal layer is formed on the substrate and serves as a catalyst for subsequent formation of a metal film on the noble metal layer. The noble metal layer is exposed to an organometallic precursor and a hydrogen source to form the metal film. The exposures can be sequential or simultaneous.

### TECHNICAL FIELD

Embodiments of the disclosure relate to halide-free metal films and halide-free methods of depositing metal films. More particularly, embodiments of the disclosure are directed to halide-free metal films formed using a noble metal film as a catalyst.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deliver precursor molecules on a substrate surface in sequential cycles. The cycle exposes the substrate surface to a first precursor, a purge gas, a second precursor and the purge gas. The first and second precursors react to form a product compound as a film on the substrate surface. The cycle is repeated to form the layer to a desired thickness.

Metal films have attractive material and conductive properties. These films have been proposed and tested for applications from front end to back-end parts of semiconductor devices. Commercially viable approaches to forming metal films use halide-containing processes or metal precursors with oxygen. Deposition of metal films for middle-of-line (MOL) and back-end-of-the-line (BEOL) integration schemes, however, require halide-free and oxygen-free processes. Halide and oxygen contamination may affect other metal films and metal nitride films, leading to negative impacts of device performance. There is, therefore, a need in the art for halide-free processes to form metal films.

### SUMMARY

One or more embodiments of the disclosure are directed to methods of forming a metal film on a semiconductor substrate. In one or more embodiments, a method of forming a metal film on a semiconductor substrate comprises: forming a noble metal layer on a substrate; exposing the noble metal layer to an organometallic precursor; and exposing the noble metal layer to a hydrogen source to form the metal film on the substrate.

Further embodiments of the disclosure are directed to methods of forming a metal film on a semiconductor substrate. In one or more embodiments, a method of forming a metal film on a semiconductor substrate comprises: forming the metal film in a process cycle comprising sequential exposure of a noble metal layer on a substrate to an organometallic precursor, purge gas, a hydrogen source, and purge gas.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1 illustrates a process flow diagram of a method in accordance with one or more embodiments of the disclosure;

FIG. 2 illustrates a cross-section schematic of a substrate being processed in accordance with one or more embodiments of the disclosure;

FIG. 3 illustrates a cross-section schematic of a substrate being processed in accordance with one or more embodiments of the disclosure;

FIG. 4 illustrates a cross-section schematic of a substrate being processed in accordance with one or more embodiments of the disclosure; and

FIG. 5 illustrates a cross-section schematic of a substrate being processed in accordance with one or more embodiments of the disclosure.

Example embodiments are described herein with reference to cross-sectional illustrations that are schematic illustrations of example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but may include deviations in shapes that result, for example, from manufacturing.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

Embodiments of the disclosure provide methods to deposit metal films from organometallic precursors using small amounts of catalytic noble metals under reducing conditions. The process is halide-free. The process can provide high selectivity, gap fill and/or ALD conformal films.

In one or more embodiments, organometallic precursors are used to deposit metallic films. A catalytic noble metal is advantageously used to increase the amount of available hydrogen (H) atoms in the film, promoting the removal of ligands. When similar processes are available, using a catalyst reduces the temperature needed for the process. The method of one or more embodiments is a halide-free process and an oxygen-free process, removing the risk of corrosion of the metallic films and removing the need for protective films. In one or more embodiments, different combinations of noble metal precursors and organometallic precursors allow for diverse deposition processes including, but not limited to, bottom-up gap fill, conformal metal deposition, and selective deposition.

The metal films of one or more embodiments are substantially free of halide. As used herein, the term “substantially free” means that there is less than about 5%, including less than about 4%, less than about 3%, less than about 2%, less than about 1%, and less than about 0.5% of halogen, on an atomic basis, in the metal film. In some embodiments, the metal film is substantially free of oxygen, and there is less than about 5%, including less than about 4%, less than about 3%, less than about 2%, less than about 1%, and less than about 0.5% of oxygen, on an atomic basis, in the metal film.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal and/or bake the substrate surface. In addition to film processing directly on the surface of the substrate itself, in the present invention, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

According to one or more embodiments, the method uses an atomic layer deposition (ALD) process. In such embodiments, the substrate surface is exposed to the precursors (or reactive gases) sequentially or substantially sequentially. As used herein throughout the specification, “substantially sequentially” means that a majority of the duration of a precursor exposure does not overlap with the exposure to a co-reagent, although there may be some overlap.

As used in this specification and the appended claims, the terms “precursor”, “reactant”, “reactive gas”, and the like are used interchangeably to refer to any gaseous species that can react with the substrate surface.

“Atomic layer deposition” or “cyclical deposition” as used herein refers to the sequential exposure of two or more reactive compounds to deposit a layer of material on a substrate surface. As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction). The substrate, or portion of the substrate is exposed sequentially to the two or more reactive compounds which are introduced into a reaction zone of a processing chamber. In a time-domain ALD process, exposure to each reactive compound is separated by a time delay to allow each compound to adhere and/or react on the substrate surface. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time-delay. Next, a second precursor or compound B is pulsed into the reaction zone followed by a second delay. During each time delay a purge gas, such as argon, is introduced into the processing chamber to purge the reaction zone or otherwise remove any residual reactive compound or by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the desired thickness.

In an aspect of a spatial ALD process, a first reactive gas and second reactive gas (e.g., hydrogen radicals) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

Without intending to be bound by theory, it is thought that the presence of halides in the structure of the metal film can pose challenges, as halide contamination may affect device performance and hence require additional removal procedures. Halides bind strongly to metals, requiring higher thermal budget, or the use of additional reagents for its removal. Additionally, halide can redeposit and poison other metal surfaces.

Previously, commercially viable approaches to form metal films use halide-based co-reactants or precursors and/or high temperature. Thus, one or more embodiments provide methods of forming metal films using a halide-free process, resulting in less contamination of the metal film, and less damage to neighboring films in the semiconductor structures, while maintaining strong device performance and shorter processing times.

In one or more embodiments, a catalytic noble metal film is formed on a substrate surface. The noble metal film then serves as a catalyst for formation of a metal film. Noble metal and metal containing films can be formed by atomic layer deposition or chemical vapor deposition for many semiconductor applications. One or more embodiments of the disclosure advantageously provide processes for atomic layer deposition or chemical vapor deposition to form noble metal films and subsequently metal films on a semiconductor substrate. In one or more embodiments, the catalytic noble metal can be deposited at different stages during device fabrication.

As described herein, in one or more embodiments, the metal films are deposited on the catalytic noble metal film using a CVD or ALD process in combination with a hydrogen source. Metal films may comprise any suitable metal known to the skilled artisan.

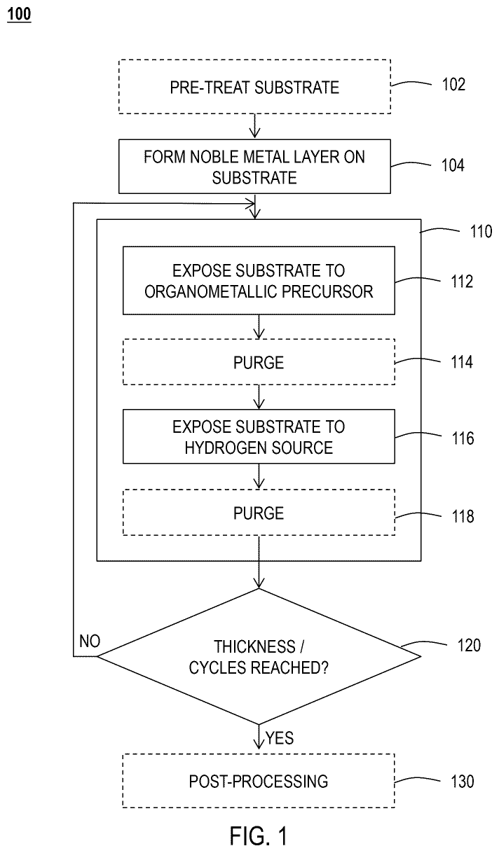

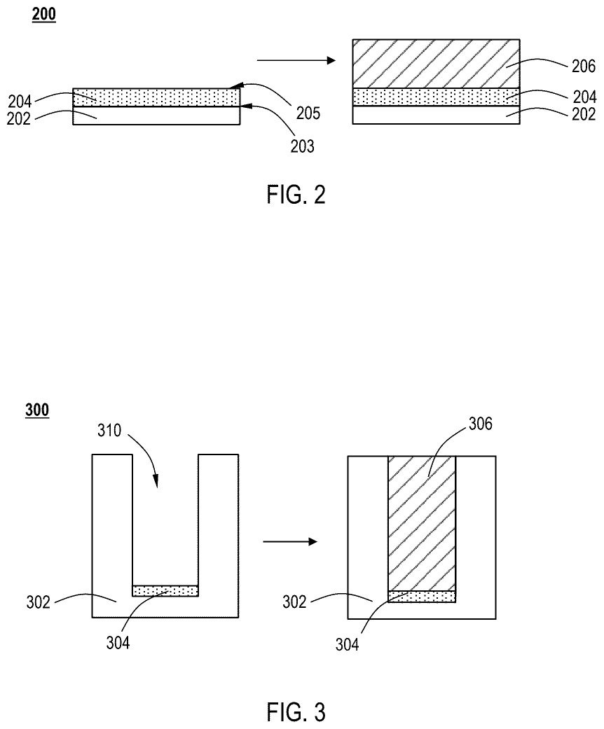

With reference to FIG. 1 and FIG. 2, one or more embodiments of the disclosure are directed to a method 100 of depositing a film. The method illustrated in FIG. 1 is representative of an atomic layer deposition (ALD) process in which the substrate or substrate surface is exposed sequentially to the reactive gases in a manner that prevents or minimizes gas phase reactions of the reactive gases. In some embodiments, the method comprises a chemical vapor deposition (CVD) process in which the reactive gases are mixed in the processing chamber to allow gas phase reactions of the reactive gases and deposition of the thin film.

In some embodiments, the method 100 includes a pre-treatment operation 102 where the substrate 202 is subjected to a pre-treatment. The pre-treatment can be any suitable pre-treatment known to the skilled artisan. Suitable pre-treatments include, but are not limited to, pre-heating, cleaning, soaking, native oxide removal, or deposition of an adhesion layer (e.g., titanium nitride (TiN)). In one or more embodiments, an adhesion layer, such as titanium nitride, is deposited at operation 102.

Referring to FIG. 1 and FIG. 2, at operation 104, a noble metal layer 204 is formed on a top surface 203 of the substrate 202. As used herein, a “substrate surface” refers to any substrate surface upon which a layer may be formed. The substrate surface may have one or more features formed therein, one or more layers formed thereon, and combinations thereof. The substrate (or substrate surface) may be pretreated prior to the deposition of the metal layer, for example, by polishing, etching, reduction, oxidation, halogenation, hydroxylation, annealing, baking, or the like.

The substrate may be any substrate capable of having material deposited thereon, such as a silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a solar array, solar panel, a light emitting diode (LED) substrate, a semiconductor wafer, or the like. In some embodiments, one or more additional layers may be disposed on the substrate such that the metal layer may be at least partially formed thereon. For example, in some embodiments, a layer comprising a metal, a nitride, an oxide, or the like, or combinations thereof may be disposed on the substrate and may have the metal layer formed upon such layer or layers.

As used herein, the term “noble metal” refers to a metallic element that is generally resistant to corrosion and oxidation, even at high temperatures. Noble metals are valuable materials that are found in nature in their raw form. In one or more embodiments, the noble metal may comprise any suitable noble metal known to the skilled artisan. In one or more embodiments, the noble metal may be selected from one or more of ruthenium (Ru), iridium (Ir), osmium (Os), rhodium (Rh), platinum (Pt), palladium (Pd), gold (Au), and silver (Ag).

As used in this specification and the appended claims, the term “noble metal-containing film” or “noble metal film” refers to a film that comprises noble metal atoms and has greater than or equal to about 1 atomic % noble metal, greater than or equal to about 2 atomic % noble metal, greater than or equal to about 3 atomic % noble metal, greater than or equal to about 4 atomic % noble metal, greater than or equal to about 5 atomic % noble metal, greater than or equal to about 10 atomic % noble metal, greater than or equal to about 15 atomic % noble metal, greater than or equal to about 20 atomic % noble metal, greater than or equal to about 25 atomic % noble metal, greater than or equal to about 30 atomic % noble metal, greater than or equal to about 35 atomic % noble metal, greater than or equal to about 40 atomic % noble metal, greater than or equal to about 45 atomic % noble metal, greater than or equal to about 50 atomic % noble metal, or greater than or equal to about 60 atomic % noble metal. In one or more embodiments, the noble metal film is a pure noble metal film. As used herein, the term “pure” means that there is substantially only the desired noble metal in the film. Thus, in some embodiments, the noble metal film has greater than or equal to about 90 atomic % noble metal, or greater than or equal to about 91 atomic % noble metal, or greater than or equal to about 92 atomic % noble metal, or greater than or equal to about 93 atomic % noble metal, or greater than or equal to about 94 noble atomic % metal, or greater than or equal to about 95 noble atomic % metal, or greater than or equal to about 96 noble atomic % metal, or greater than or equal to about 97 atomic % noble metal, or greater than or equal to about 98 atomic % noble metal, or greater than or equal to about 99 atomic % noble metal, or about 100 atomic % noble metal.

The noble metal layer 204 may be formed by any suitable deposition process. In some embodiments, the noble metal layer 204 is formed by one or more of atomic layer deposition (ALD) or chemical vapor deposition (CVD).

Referring to FIG. 1, at deposition 110, a process is performed to deposit a metal film 206 on the noble metal layer 204 (or noble metal surface 205). The deposition process can include one or more operations to form the metal film 206 on the substrate. In operation 112, the substrate (or substrate surface) with the noble metal layer 204 thereon is exposed to an organometallic precursor to deposit a precursor film on the noble metal layer 204 (or noble metal surface 205). The organometallic precursor can be any suitable metal compound that can react with (i.e., adsorb or chemisorb onto) the noble metal layer 204 (or noble metal surface 205) to leave a metal species on the noble metal layer 204 (or noble metal surface 205).

In one or more embodiments, the organometallic precursor comprises any suitable precursor containing one of the desired metals. In one or more embodiments, the metal is selected from one of more of vanadium (V), niobium (Nb), tantalum (Ta), chromium (Cr), molybdenum (Mo), tungsten (W), manganese (Mn), rhenium (Re), iron (Fe), and cobalt (Co). In one or more embodiments, the metal is selected from the group consisting of vanadium (V), niobium (Nb), tantalum (Ta), chromium (Cr), molybdenum (Mo), tungsten (W), manganese (Mn), rhenium (Re), iron (Fe), and cobalt (Co). In other embodiments, the metal consists essentially of vanadium (V), niobium (Nb), tantalum (Ta), chromium (Cr), molybdenum (Mo), tungsten (W), manganese (Mn), rhenium (Re), iron (Fe), or cobalt (Co). In further embodiments, the metal consists of vanadium (V), niobium (Nb), tantalum (Ta), chromium (Cr), molybdenum (Mo), tungsten (W), manganese (Mn), rhenium (Re), iron (Fe), or cobalt (Co).

At operation 114, the processing chamber is optionally purged to remove unreacted organometallic precursor, reaction products and by-products. As used in this manner, the term “processing chamber” also includes portions of a processing chamber adjacent to the substrate surface without encompassing the complete interior volume of the processing chamber. For example, in a sector of a spatially separated processing chamber, the portion of the processing chamber adjacent the substrate surface is purged of the organometallic precursor by any suitable technique including, but not limited to, moving the substrate through a gas curtain to a portion or sector of the processing chamber that contains none or substantially none of the organometallic precursor. In one or more embodiments, purging the processing chamber comprises applying a vacuum. In some embodiments, purging the processing chamber comprises flowing a purge gas over the substrate. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas comprises one or more of hydrogen (H₂), nitrogen (N₂), helium (He), and argon (Ar).

At operation 116, the substrate is exposed to a hydrogen source to react with the organometallic precursor to leave a metal film on the substrate surface. In one or more embodiments, the catalyst changes the oxidative addition-reductive elimination of hydrogen (H₂) on the precursor to a hydrogenation reaction of the ligands. The hydrogen source may comprise any suitable hydrogen source known to the skilled artisan. In one or more embodiments, the hydrogen source comprises one or more of hydrogen (H₂), ammonia (NH₃), hydrazine (N₂H₄), silanes, boranes, formic acid, alcohols (isopropanol, and the like).

As used herein, the term “silane” refers to a compound SiR′₄, wherein R′ is independently selected from hydrogen (H) or alkyl. In some embodiments, the silane can be substituted or unsubstituted. As used herein, the term “borane” refers to a compound BR′₃, wherein R′ is independently selected from hydrogen (H) or alkyl. Unless otherwise indicated, the term “lower alkyl,” “alkyl,” or “alk” as used herein alone or as part of another group includes both straight and branched chain hydrocarbons, containing 1 to 20 carbons, in the normal chain, such as methyl, ethyl, propyl, isopropyl, butyl, t-butyl, isobutyl, pentyl, hexyl, isohexyl, heptyl, 4,4-dimethylpentyl, octyl, 2,2,4-trimethyl-pentyl, nonyl, decyl, undecyl, dodecyl, the various branched chain isomers thereof, and the like. Such groups may optionally include up to 1 to 4 substituents.

At operation 118, the processing chamber is optionally purged after exposure to the hydrogen source. Purging the processing chamber in operation 118 can be the same process or different process than the purge in operation 114. Purging the processing chamber, portion of the processing chamber, area adjacent the substrate surface, etc., removes unreacted reactants, reaction products and by-products from the area adjacent the substrate surface.

At decision 120, the thickness of the deposited metal film, or number of cycles of organometallic precursor and hydrogen source is considered. If the deposited film has reached a predetermined thickness or a predetermined number of process cycles have been performed, the method 100 moves to an optional post-processing operation 130. In some embodiments, the process cycle comprises sequential exposure of the substrate to the organometallic precursor, purge gas, hydrogen source, and purge gas. If the thickness of the deposited film or the number of process cycles has not reached the predetermined threshold, the method 100 returns to operation 110 to expose the substrate surface to the organometallic precursor again in operation 112 and continuing.

The optional post-processing operation 130 can be, for example, a process to modify film properties (e.g., annealing) or a further film deposition process (e.g., additional ALD or CVD processes) to grow additional films. In some embodiments, the optional post-processing operation 130 can be a process that modifies a property of the deposited metal film. In some embodiments, the optional post-processing operation 130 comprises annealing the as-deposited metal film. In some embodiments, annealing is done at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the film is annealed for a predetermined time in the range of about 15 seconds to about 90 minutes, or in the range of about 1 minute to about 60 minutes. In some embodiments, annealing the as-deposited metal film increases the density, decreases the resistivity and/or increases the purity of the metal film.

The method 100 can be performed at any suitable temperature depending on, for example, the noble metal, the organometallic precursor, the hydrogen source, or thermal budget of the device. In one or more embodiments, the use of high temperature processing may be undesirable for temperature-sensitive substrates, such as logic devices. In some embodiments, exposure to the organometallic precursor (operation 112) and the hydrogen source (operation 116) occur at the same temperature. In some embodiments, the substrate is maintained at a temperature in a range of about 150° C. to about 400° C., or about 150° C. to about 650° C., or about 150° C. to about 300° C.

In some embodiments, exposure to the organometallic precursor (operation 112) occurs at a different temperature than the exposure to the hydrogen source (operation 116). In some embodiments, the substrate is maintained at a first temperature in a range of about 150° C. to about 400° C., or about 150° C. to about 650° C., or about 150° C. to about 300° C. for the exposure to the organometallic precursor, and at a second temperature in the range of about 150° C. to about 400° C., or about 150° C. to about 650° C., or about 150° C. to about 300° C. for exposure to the hydrogen source.

In one or more embodiments, the deposition process is carried out in a process volume at pressures ranging from 0.1 m Torr to 10 Torr, or in a range of from 0.5 m Torr to 100 m Torr, including a pressure of about 0.1 m Torr, about 1 mTorr, about 10 m Torr, about 100 m Torr, about 500 mTorr, about 1 Torr, about 2 Torr, about 3 Torr, about 4 Torr, about 5 Torr, about 6 Torr, about 7 Torr, about 8 Torr, about 9 Torr, and about 10 Torr.

In the embodiment illustrated in FIG. 1, at deposition operation 110 the noble metal layer 204 (or noble metal surface 205) is exposed to the organometallic precursor and the hydrogen source sequentially. In another, un-illustrated, embodiment, the noble metal layer 204 (or noble metal surface 205) is exposed to the organometallic precursor and the hydrogen source simultaneously in a CVD reaction. In a CVD reaction, the substrate (or substrate surface) can be exposed to a gaseous mixture of the organometallic precursor and hydrogen source to deposit a metal film having a predetermined thickness. In the CVD reaction, the metal film can be deposited in one exposure to the mixed reactive gas or can be multiple exposures to the mixed reactive gas with purges between.

In some embodiments, the metal film formed comprises elemental metal. Stated differently, in some embodiments, the metal film comprises a metal film comprising a metal. In some embodiments, the metal film consists essentially of a metal. As used in this manner, the term “consists essentially of a metal” means that the metal film is greater than or equal to about 80%, 85%, 90%, 95%, 98%, 99% or 99.5% the metal, on an atomic basis. Measurements of the composition of the metal film refer to the bulk portion of the film, excluding interface regions where diffusion of elements from adjacent films may occur.

As used in this specification and the appended claims, the term “metal-containing film” or “metal film” refers to a film that comprises metal atoms and has greater than or equal to about 1 atomic % metal, greater than or equal to about 2 atomic % metal, greater than or equal to about 3 atomic % metal, greater than or equal to about 4 atomic % metal, greater than or equal to about 5 atomic % metal, greater than or equal to about 10 atomic % metal, greater than or equal to about 15 atomic % metal, greater than or equal to about 20 atomic % metal, greater than or equal to about 25 atomic % metal, greater than or equal to about 30 atomic % metal, greater than or equal to about 35 atomic % metal, greater than or equal to about 40 atomic % metal, greater than or equal to about 45 atomic % metal, greater than or equal to about 50 atomic % metal, or greater than or equal to about 60 atomic % metal. In one or more embodiments, the metal film is a pure metal film. As used herein, the term “pure” means that there is substantially only the desired metal in the film. Thus, in some embodiments, the metal film has greater than or equal to about 90 atomic % metal, or greater than or equal to about 91 atomic % metal, or greater than or equal to about 92 atomic % metal, or greater than or equal to about 93 atomic % metal, or greater than or equal to about 94 atomic % metal, or greater than or equal to about 95 atomic % metal, or greater than or equal to about 96 atomic % metal, or greater than or equal to about 97 atomic % metal, or greater than or equal to about 98 atomic % metal, or greater than or equal to about 99 atomic % metal, or about 100 atomic % metal.

The metal of the metal film may comprise any suitable metal known to the skilled artisan. In one or more embodiments, the metal film comprises a metal selected from one of more of vanadium (V), niobium (Nb), tantalum (Ta), chromium (Cr), molybdenum (Mo), tungsten (W), manganese (Mn), rhenium (Re), iron (Fe), and cobalt (Co). In one or more embodiments, the metal film comprises a metal selected from the group consisting of vanadium (V), niobium (Nb), tantalum (Ta), chromium (Cr), molybdenum (Mo), tungsten (W), manganese (Mn), rhenium (Re), iron (Fe), and cobalt (Co). In other embodiments, the metal film consists essentially of a metal selected from the group consisting of vanadium (V), niobium (Nb), tantalum (Ta), chromium (Cr), molybdenum (Mo), tungsten (W), manganese (Mn), rhenium (Re), iron (Fe), and cobalt (Co). In further embodiments, the metal film consists of a metal selected from the group consisting of vanadium (V), niobium (Nb), tantalum (Ta), chromium (Cr), molybdenum (Mo), tungsten (W), manganese (Mn), rhenium (Re), iron (Fe), and cobalt (Co).

The deposition operation 110 can be repeated to form a metal film having a predetermined thickness. In some embodiments, the deposition operation 110 is repeated to provide one or more of a metal film, such as a film comprising a metal (elemental metal), having a thickness in the range of about 0.3 nm to about 100 nm, or in the range of about 30 Å to about 10 μm.

Referring to FIG. 3, in one or more embodiments of the disclosure are directed to methods of depositing metal films in high aspect ratio features 310. A high aspect ratio feature is a trench, via or pillar having a height:width ratio greater than or equal to about 10, 20, 50, 100, or more. As illustrated in FIG. 3, one or more embodiments of the disclosure are directed to methods for bottom-up gapfill of a feature. A bottom-up gapfill process fills the feature 310 from the bottom versus a conformal process which fills the feature from the bottom and sides. In some embodiments, the feature has a noble metal layer 304 at the bottom and the gapfill metal film 306 is formed on the noble metal layer 304. The metal film 306 fills the feature in a bottom-up manner. In one or more embodiments, the catalytic noble metal film 304 is formed at the bottom of a feature 310, e.g., trench. In one or more embodiments, the noble metal film 304 then serves as a catalyst for formation of a metal gap fill film 306. In some embodiments, the metal gap fill film 306 is substantially free of a seam. In some embodiments, chemical mechanical planarization is not needed to clean the top surface of the metal gap fill film 306 material.

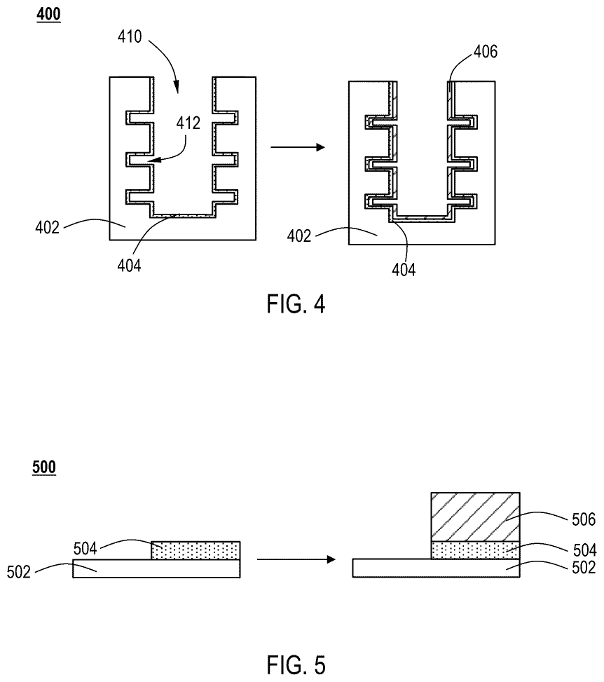

Referring to FIG. 4, in one or more embodiments a metal film 406 is deposited conformally on the high aspect ratio feature 410. As used in this manner, a conformal film has a thickness near the top of the feature that is in the range of about 80 to 120% of the thickness at the bottom of the feature. In one or more embodiments, a conformal layer of noble metal 404 is formed on a substrate surface. In one or more embodiments, the noble metal layer 404 serves as a catalyst for formation of a subsequent metal film 406. In some embodiments, the metal film 406 forms conformally on the noble metal layer 404 by atomic layer deposition (ALD). In one or more embodiments, the presence of the catalytic noble metal layer 404 changes a chemical vapor deposition (CVD) process into an ALD one (metal precursor, purge, hydrogen source, purge), providing good conformality.

As illustrated in FIG. 5, in one or more embodiments, a noble metal layer 504 is formed on a substrate 502. The noble metal layer 504 is used as a seed layer for selective deposition of a metal layer 506. Selective deposition of the metal layer 506 occurs at lower temperature than without the catalyst layer (lower temperature enhances selectivity).

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or it can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system,” and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at the front end of the cluster tool. Any suitable cluster tool may be adapted for the present disclosure. The exact arrangement and combination of chambers, however, may be altered for purposes of performing specific steps of a process as described herein. Processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as rapid thermal processing (RTP), plasma nitridation, degas, orientation, hydroxylation, and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed, and unloaded before another substrate is processed. The substrate can also be processed in a continuous manner, similar to a conveyer system, in which multiple substrate are individually loaded into the first part of the chamber, move through the chamber, and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc. processes throughout the carousel path.

During processing, the substrate can be heated or cooled. Such heating or cooling can be accomplished by any suitable means including, but not limited to, changing the temperature of the substrate support, and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled locally to change the substrate temperature. In some embodiments, a heater/cooler is positioned within the chamber adjacent to the substrate surface to convectively change the substrate temperature.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

The disclosure is now described with reference to the following examples. Before describing several exemplary embodiments of the disclosure, it is to be understood that the disclosure is not limited to the details of construction or process steps set forth in the following description. The disclosure is capable of other embodiments and of being practiced or being carried out in various ways.

### EXAMPLES

### Example 1: Atomic Layer Deposition of Metal Films

General procedure: A silicon substrate is placed in a processing chamber. A noble metal layer is formed on the silicon substrate. An organometallic precursor is flowed into the processing chamber in an atmosphere of nitrogen (N₂) gas over the silicon substrate leaving a metal-precursor terminated surface. Unreacted precursor and byproducts are then purged out of the chamber. Next, a hydrogen source is then introduced into the chamber that reacts with the surface-bound metal species. Again, excess hydrogen source and byproducts are removed from the chamber. The resultant material on the substrate is a metal film.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. In one or more embodiments, the particular features, structures, materials, or characteristics are combined in any suitable manner.

Although the disclosure herein has been described with reference to particular embodiments, it is to be understood that these embodiments are merely illustrative of the principles and applications of the present disclosure. It will be apparent to those skilled in the art that various modifications and variations can be made to the method and apparatus of the present disclosure without departing from the spirit and scope of the disclosure. Thus, it is intended that the present disclosure includes modifications and variations that are within the scope of the appended claims and their equivalents.

What is claimed is:

1. A method of forming a metal film on a semiconductor substrate, the method comprising:
forming a noble metal layer on a substrate;
exposing the noble metal layer to an organometallic precursor; and
exposing the noble metal layer to a hydrogen source to form the metal film on the substrate.

2. The method of claim 1, wherein the noble metal layer comprises a noble metal selected from one or more of ruthenium (Ru), iridium (Ir), osmium (Os), rhodium (Rh), platinum (Pt), palladium (Pd), gold (Au), and silver (Ag).

3. The method of claim 1, wherein the organometallic precursor comprises a metal selected from one or more of vanadium (V), niobium (Nb), tantalum (Ta), chromium (Cr), molybdenum (Mo), tungsten (W), manganese (Mn), rhenium (Re), iron (Fe), and cobalt (Co).

4. The method of claim 1, wherein the hydrogen source is selected from one or more of hydrogen (H₂), ammonia (NH₃), hydrazine (N₂H₄), silanes, boranes, formic acid, and alcohols.

5. The method of claim 1, wherein the method is one or more of chemical vapor deposition or atomic layer deposition.

6. The method of claim 1, wherein the hydrogen source is reacted with the organometallic precursor at a temperature in a range of from 150° C. to 400° C.

7. The method of claim 1, wherein the metal film comprises one or more of a vanadium (V) film, a niobium (Nb) film, a tantalum (Ta) film, a chromium (Cr) film, a molybdenum (Mo) film, a tungsten (W) film, a manganese (Mn) film, a rhenium (Re) film, an iron (Fe) film, and a cobalt (Co) film.

8. The method of claim 1, wherein the noble metal layer is exposed to the organometallic precursor and the hydrogen source sequentially.

9. The method of claim 1, wherein the noble metal layer is exposed to the organometallic precursor and the hydrogen source simultaneously.

10. The method of claim 1, further comprising purging the substrate of the organometallic precursor prior to exposing the substrate to the hydrogen source.

11. The method of claim 10, wherein purging comprises one or more of applying a vacuum or flowing a purge gas over the substrate.

12. The method of claim 1, further comprising repeating the method to provide the metal film having a thickness of about 0.3 to about 100 nm.

13. The method of claim 11, wherein the purge gas comprises one or more of hydrogen (H₂), nitrogen (N₂), helium (He), and argon (Ar).

14. A method of forming a metal film on a semiconductor substrate, the method comprising:
forming the metal film in a process cycle comprising sequential exposure of a noble metal layer on a substrate to an organometallic precursor, purge gas, a hydrogen source, and purge gas.

15. The method of claim 14, wherein the noble metal layer comprises a noble metal selected from one or more of ruthenium (Ru), iridium (Ir), osmium (Os), rhodium (Rh), platinum (Pt), palladium (Pd), gold (Au), and silver (Ag).

16. The method of claim 14, wherein the organometallic precursor comprises a metal selected from one or more of vanadium (V), niobium (Nb), tantalum (Ta), chromium (Cr), molybdenum (Mo), tungsten (W), manganese (Mn), rhenium (Re), iron (Fe), and cobalt (Co).

17. The method of claim 14, wherein the hydrogen source is selected from one or more of hydrogen (H₂), ammonia (NH₃), hydrazine (N₂H₄), silanes, boranes, formic acid, and alcohols.

18. The method of claim 14, wherein the hydrogen source is reacted with the organometallic precursor at a temperature in a range of from 150° C. to 400° C.

19. The method of claim 14, wherein the metal film comprises one or more of a vanadium (V) film, a niobium (Nb) film, a tantalum (Ta) film, a chromium (Cr) film, a molybdenum (Mo) film, a tungsten (W) film, a manganese (Mn) film, a rhenium (Re) film, an iron (Fe) film, and a cobalt (Co) film.

20. The method of claim 14, wherein the purge gas comprises one or more of hydrogen (H₂), nitrogen (N₂), helium (He), and argon (Ar).
